(19) United States
(12) Patent Application Publication
(10) Pub. No.: US 2025/0102349 A1
(43) Pub. Date: Mar. 27, 2025

(54) WEIGHING DEVICE

(71) Applicant: METRYX LTD., Bristol (GB)

(72) Inventors: Gregor Robert ELLIOTT, Gloucester (GB); Sam OWENS, Caldicot (GB)

(21) Appl. No.: 18/727,531

(22) PCT Filed: Jan. 13, 2023
(86) PCT No.: PCT/EP2023/050705

§ 371 Date: Jul. 9, 2024

(30) Foreign Application Priority Data
Jan. 14, 2022 (GB) 2200464.2

(51) Int. Cl. G01G 21/22; G01G 21/26

(52) U.S. Cl. CPC G01G 21/22; G01G 21/26

(57) ABSTRACT

A weighing device for performing a weight measurement on a semiconductor wafer having a specific diameter, the weighing device comprising a weighing pan for supporting the wafer during the weight measurement, wherein: the weighing pan is grounded; and the weighing pan is configured to extend over at least 25% of an area of a surface of the wafer that faces the weighing pan.

### FIELD OF THE INVENTION

The present invention relates to a weighing device for performing a weight measurement on a semiconductor wafer.

### BACKGROUND OF THE INVENTION

Microelectronic devices are fabricated on semiconductor wafers using a variety of techniques, e.g. including deposition techniques (CVD, PECVD, PVD, etc) and removal techniques (e.g. chemical etching, CMP, etc). Semiconductor e.g. silicon wafers may be further treated in ways that alter their mass e.g. by cleaning, ion implantation, lithography and the like. These treatment techniques typically cause a change in the mass at or on the surface of the semiconductor wafer. The configuration of the changes to the surface are often vital to the functioning of the device, so it is desirable for quality control purposes to assess wafers during production in order to determine whether they have the correct configuration.

Known types of measurement technique may depend on the type of wafer treatment or the properties of materials created by the treatment. For example, treated wafers can be measured using ellipsometry when they contain dielectrics, or wafers can be tested using resistivity probes when conductive metals are deposited thereon.

WO/2002/003449 discloses an apparatus and method for investigating semiconductor wafers in which changes in the mass of the wafer are determined to assess various properties of the wafer, e.g. to enable fabrication of the wafer to be monitored. A common method of obtaining mass measurements is to use a very sensitive force sensor to measure the force (weight) due to gravity. At medium levels of accuracy this force can be assumed to be due solely to the mass of the wafer. However, if higher levels of accuracy are needed, other forces may need to be taken into account.

One such force disclosed in WO/2002/003449 is caused by atmospheric buoyancy. In semiconductor metrology, a semiconductor wafer is usually measured in an atmosphere (i.e. not a vacuum). The wafer therefore displaces a volume of this atmosphere, which causes an up thrust force. The up-thrust force depends on the atmospheric (air) density, which in turn depends on numerous factors including temperature, atmospheric pressure, relative humidity and air composition. The up-thrust force reduces the apparent weight of the wafer detected by the force sensor.

WO/2002/003449 discloses a method of compensating or correcting for the effect of atmospheric buoyancy. Sensors are provided to monitor temperature, pressure and relative humidity. A processor receives measurements from these sensors and uses them to calculate the air density, which can be used to compensate for buoyancy in a corresponding weight measurement. The processor can calculate buoyancy from the calculated air density, together with the weight measurement and density information about the wafer.

WO2009/044121 discloses that when performing sensitive mass measurements on wafers where atmospheric buoyancy is eliminated or suitably compensated, other (typically smaller) errors become noticeable. For example, such errors may be caused by pressure effects due to atmospheric movement (air currents) around the wafer and electrostatic forces due to charges on the wafer or surrounding materials. Such errors may also be apparent when atmospheric buoyancy is not eliminated or suitably compensated.

Electrostatic attraction forces arise when there is a voltage potential difference between the wafer and surrounding material (e.g. walls of an enclosure). Static electricity charges can range from 5-10 V to several kilovolts in magnitude. On a wafer, charges can exist on its surface (surface charge) or within its body (substrate, embedded charge). In the latter case, the charge may be trapped by an insulating coating layer such as silicon oxide or silicon nitride. Charges can be caused by a variety of means, e.g. earlier processing or fabrication steps, tribology, contact electrification, etc. Ionisation devices have previously been proposed as a way of reducing static electricity. However, they are limited because they can only neutralise surface charges and often have unbalanced positive and negative ion streams, which causes them to leave a residual charge.

As shown in FIG. 1, which corresponds to FIG. 3 of WO2009/044121, WO2009/044121 discloses an apparatus 1 that includes a chamber 2 arranged to enclose a semiconductor wafer 3 and various measuring instruments during a weight measurement. The wafer 3 is supported on a pan 4 of a weighing instrument 5, e.g. a suitable microbalance. Thus, the weight of the wafer 3 can be measured by the weighing instrument 5 via the pan 4.

The chamber 2 includes a faraday cage 6 that is electrically connected to ground 7, and that is arranged to enclose the wafer 3. The faraday cage 6 includes a door (not shown) for delivery and removal of the wafer 3. When the door is closed, any electrostatic charges in or on the wafer 3 are isolated within the faraday cage 6.

The pan 4 of the weighing instrument 5 is located inside the faraday cage 6, to permit the weight of the wafer 3 to be measured by the weighing instrument 5 when the wafer 3 is enclosed within the faraday cage 6.

The apparatus 1 further includes a second weighing instrument 8 with a second pan 9 that supports the weight of the faraday cage 6. The weight of the faraday cage 6 can therefore be measured by the second weighing instrument 8. The weight of the wafer 3 and the weight of the faraday cage 6 are therefore measured independently. This permits a change in the measured weight of the faraday cage 6 caused by placing the wafer 3 inside it to be recorded. This change in weight is due to the electrostatic interaction between the wafer 3 and the faraday cage 6. Since the electrostatic interaction will have an equal and opposite effect on the wafer 3, it is possible to use the change in weight recorded on the second weighing instrument 8 to correct the weight of the wafer 3 measured by the first weighing instrument 5 for the effects of the electrostatic interaction. This correction may be carried out in addition to atmospheric buoyancy compensation and is performed by a processor 10.

The apparatus 1 disclosed in WO2009/044121 is effective at counteracting measurement errors due to electrostatic attraction forces on the wafer 3. However, this arrangement requires the provision of various additional features, including the faraday cage 6, second weighing instrument 8 and second pan 9. These additional features increase the complexity and cost of the apparatus 1.

### SUMMARY OF THE INVENTION

The present invention aims to provide a simpler arrangement to that disclosed in WO2009/044121 for reducing or removing the effect of electrostatic forces on a weight force measurement of a semiconductor wafer.

Semiconductor wafers are typically thin disks (e.g. 200 mm or 300 mm in diameter and 1 mm thick). This means the majority of any electrostatic force acts normal to the plane of the wafer, i.e. perpendicular to the bottom surface of the wafer (the surface that faces the pan) and/or perpendicular to the top surface of the wafer (the surface opposite to the bottom surface).

The present inventors have realised that electrostatic forces from the bottom surface of the wafer can be a significant source of the weight force measurement error caused by electrostatic forces.

In particular, charges trapped on the bottom surface of the wafer may be attracted to metalwork in the weighing device and/or metalwork in a base of a measurement chamber, for example. Such electrostatic forces will cause the weight force measurement for the wafer to be erroneously increased, due to the additional electrostatic force, which will lead to a mass of the wafer calculated using the weight force measurement being erroneously high.

The present inventors have realised that the error in a weight force measurement due to electrostatic forces can therefore be significantly reduced by preventing and/or reducing such electrostatic forces caused by charges on the bottom surface of the wafer.

At its most general, the present invention therefore proposes providing a weighing device with a pan that shields electrostatic charges on some or all of a bottom surface of the wafer (the surface that is supported by the pan).

Therefore, any charge trapped on the bottom surface of the wafer that is shielded by the pan will result in an attractive force between the wafer and the pan. Such an attractive force will not affect the weight measurement, because the attractive forces on the wafer and pan will be equal and opposite. As such, the effects of electrostatic forces on the accuracy of the weight measurement will be reduced or removed.

In general, this effect can be achieved by providing a pan that is connected to ground and that covers some or all of the bottom surface of the wafer, so that any charge trapped on the bottom surface of the wafer that is covered by the pan will result in an attractive force between the wafer and the pan.

According to a first aspect of the present invention there is provided a weighing device for performing a weight measurement on a semiconductor wafer having a specific diameter, the weighing device comprising a weighing pan for supporting the wafer during the weight measurement, wherein: the weighing pan is grounded; and the weighing pan is configured to extend over at least 25% of an area of a surface of the wafer that faces the weighing pan.

Therefore, charges trapped on at least 25% of the area of the surface of the wafer that faces the weighing pan will result in an attractive force between the wafer and the pan. Such an attractive force will not affect the weight measurement, because the attractive forces on the wafer and pan will be equal and opposite. The weighing pan will therefore shield electrostatic charges on at least 25% of the area of the surface of the wafer that faces the weighing pan. This may significantly reduce errors in the weight measurement caused by electrostatic forces.

The weighing device according to the first aspect of the present invention may have any one, or, where compatible, any combination of the following optional features.

Performing a weight measurement on the semiconductor wafer may comprise performing a weight force measurement on the semiconductor wafer.

Performing a weight measurement on the semiconductor wafer may comprise generating a measurement output that is indicative of the weight of the semiconductor wafer.

Performing a weight measurement on the semiconductor wafer may comprise measuring a weight of the semiconductor wafer, or measuring a difference between the weight of the semiconductor wafer and the weight of another article, such as a reference weight or a reference wafer.

The weighing device may be configured to calculate information relating to the mass of the wafer based on at least the weight measurement, such as the mass of the wafer or a change in the mass of the wafer.

The weighing device is for performing a weight measurement on a semiconductor wafer having a specific diameter. Specifically, the weighing device may be configured or adapted for performing the weight measurement on the semiconductor wafer having the specific diameter.

Typically, a semiconductor wafer processing or metrology apparatus is configured to handle a specific diameter of semiconductor wafer, such as 200 mm or 300 mm, and cannot be used with semiconductor wafers with other diameters. For example, typically it is impossible to upgrade an apparatus configured for 200 mm diameter wafers to handle 300 mm diameter wafers, and downgrading an apparatus configured to handle 300 mm diameter wafers would typically require refitting the apparatus, for example by changing a wafer transport system, a weighing pan, and other elements.

A weighing pan may refer to any part of the weighing device that supports the weight of the wafer during the weight measurement. The weighing pan may alternatively be referred to as a measurement area onto which the semiconductor wafer is loaded to perform the weight measurement.

The weighing pan may alternatively be referred to as a pan, or a balance pan.

Supporting the wafer during the weight measurement means that the weight of the wafer is received by the weighing pan.

Typically the weighing pan supports a bottom surface of the wafer that faces the weighing pan.

The weighing pan being grounded means that the weighing pan is electrically connected to ground.

The weighing pan is configured to extend over at least 25% of the area of the surface of the wafer that faces the weighing pan when the wafer is supported by the weighing pan.

The surface of the wafer that faces the weighing pan when the wafer is supported by the weighing pan may be referred to as a bottom surface of the wafer.

Extending over at least 25% of the area of the surface of the wafer may mean extending across at least 25% of the area of the surface of the wafer, or covering at least 25% of the area of the surface of the wafer, or opposing at least 25% of the area of the surface of the wafer, or spanning at least 25% of the area of the surface of the wafer, or overlapping at least 25% of the area of the surface of the wafer.

Extending over at least 25% of the area of the surface of the wafer may mean that at least 25% of the area of the surface of the wafer is opposite to a surface of the weighing pan, or faces the surface of the weighing pan, when the wafer is supported by the weighing pan.

The weighing pan being configured to extend over at least 25% of the area of the surface of the wafer that faces the weighing pan may mean that a shape or area defined by (or enclosed by, or surrounded by) an outer edge (or peripheral edge, or periphery, or circumferential edge, or circumference, or boundary) of the weighing pan extends over at least 25% of the area of the surface of the wafer that faces the weighing pan.

Within this shape or area, the weighing pan does not necessarily need to be continuous in order to shield electrostatic charges on the bottom surface of the wafer. For example, the weighing pan may have one or more holes or perforations, such as a perforated configuration or a grid configuration. Such an arrangement may reduce a total weight of the weighing pan. Alternatively, the weighing pan may be continuous.

For example, the weighing pan may comprise a mesh or grid, for example a wire mesh or wire grid, or a plurality of wires, for example a plurality of parallel wires. The mesh, grid or plurality of wires may be configured to directly contact and support the wafer when the wafer is loaded on the weighing pan. The mesh, grid or plurality of wires may be attached to a frame, for example a circular or cylindrical frame, of the weighing pan.

The shape or area defined by (or enclosed by, or surrounded by) the outer edge (or peripheral edge, or periphery, or circumferential edge, or circumference, or boundary) of the weighing pan may be referred to as a shielding area of the weighing pan. This shielding area may be continuous or may include one or more holes or perforations.

In other words, the areas of any holes, perforations, gaps, etc. in the weighing pan may count towards the “at least 25% of the area of the surface of the wafer” that the weighing pan extends over.

In other words, the area mentioned here may be a total area extended over by the weighing pan including the areas of any holes or perforations in the weighing pan.

The weighing pan being configured to extend over at least 25% of the area of a surface of the wafer that faces the weighing pan may mean that a surface of the weighing pan that faces the wafer extends over at least 25% of the area of the surface of the wafer.

Again, this may mean that a shape or area defined by an outer edge (or peripheral edge, or periphery, or circumferential edge, or circumference, or boundary) of the surface of the weighing pan extends over at least 25% of the area of the surface of the wafer that faces the weighing pan.

Put another way, a surface of the weighing pan that is configured to shield electrostatic charges on the surface of the wafer that faces the weighing pan is configured to extend over at least 25% of the area of the surface of the wafer that faces the weighing pan. This shielding surface may be continuous, or may include one or more (or a plurality of) perforations or holes.

The surface of the weighing pan that faces the wafer may be configured to be substantially parallel to the surface of the wafer when the wafer is supported by the weighing pan.

The weighing pan may be circular, or substantially circular.

The surface of the weighing pan that faces the wafer may be circular, or substantially circular.

The weighing device may be for performing a weight measurement on a semiconductor wafer having a diameter of 200 mm, or 300 mm, or 450 mm.

The weighing pan may be configured to extend over at least 30%, or at least 35%, or at least 40%, or at least 45%, or at least 50%, or at least 55%, or at least 60%, or at least 65%, or at least 70%, or at least 75%, or at least 80%, or at least 85%, or at least 90%, or at least 95%, or at least 100% of the area of the surface of the wafer that faces the weighing pan. Specifically, where the weighing pan extends over a greater area of the surface of the wafer that faces the weighing pan, a greater proportion of the electrostatic charge on the surface of the wafer will be shielded by the weighing pan, which will reduce the weighing error caused by the electrostatic charge.

A surface of the weighing pan that faces the wafer may be a substantially continuous surface, for example a substantially continuous sheet or plate of material.

Alternatively, a surface of the weighing pan that faces the wafer may be discontinuous, for example it may include one or more holes or perforations. For example, the surface may be a perforated surface, or may have a grid or grate configuration.

A surface of the weighing pan that faces the wafer may have a thickness of less than 1 mm.

The weighing pan may only face the bottom surface of the wafer.

Alternatively, the weighing pan may be configured to at least partly enclose the wafer supported by the weighing pan.

At least partly enclosing the wafer may mean that the weighing pan at least partly covers an edge of the wafer and/or at least partly covers a top surface of the wafer that is opposite to the bottom surface of the wafer.

The weighing pan may comprise a surface that extends over (or extends across, or opposes, or covers) at least part of a top surface of the wafer supported by the weighing pan.

In this manner, the weighing pan may shield charges on other surfaces of the wafer, and may therefore further reduce electrostatic forces between the wafer and surrounding objects such as a measurement enclosure.

The weighing pan may enclose the wafer. For example, the weighing pan may form a chamber or housing in which the wafer is received. In this case, the weighing pan may have an opening, which may be closable, through which the wafer can be inserted into the weighing pan.

The weighing pan may be configured to form a faraday cage around the wafer supported by the weighing pan. The weighing pan may therefore shield all charges on the wafer, such that all charges on the wafer lead to an attractive force between the wafer and the weighing pan.

The weighing device may comprise a counterweight that cancels out part of the weight of the semiconductor wafer loaded on the weighing pan. Therefore, the weighing device may measure a difference between a weight of the semiconductor wafer and a counterbalancing force provided by the counterweight.

An advantage of such an arrangement is that the difference being measured will be significantly smaller than the weight of the wafer and can therefore be measured using a higher resolution load cell, giving a better resolution of measurement. In particular, the best resolution available for a load cell is typically a function of the maximum weight that the load cell can measure, such that load cells that measure smaller weights generally have better resolution than load cells that measure larger weights. When weighing semiconductor wafers, the load cell resolution can be a major limiting factor in the overall resolution of the measurement.

The counterweight may be a second semiconductor wafer. Such a second semiconductor wafer may be referred to as a counterbalance wafer.

The counterweight (e.g. counterbalance wafer) may have substantially the same density as the semiconductor wafer.

The counterweight (e.g. counterbalance wafer) may have substantially the same volume as the semiconductor wafer.

Where the counterweight is a counterbalance wafer, the counterbalance wafer and the semiconductor wafer being measured may have substantially the same volume and density, and may be measured under the same environmental conditions. Therefore, the buoyancy forces acting on the semiconductor wafer and the counterbalance wafer may be substantially the same. This means that changes in the buoyancy force will be equally experienced by both the semiconductor wafer and the counterbalance wafer and may effectively cancel each other out. This may reduce or remove the need for measurement correction due to environmental conditions and may improve repeatability of the measurement.

The weighing device may comprise a second weighing pan for supporting the counterbalance wafer, and the second weighing pan may be configured to extend over at least 25% of an area of a surface of the counterbalance wafer that faces the second weighing pan. The second weighing pan may have any of the features of the weighing pan described above (which may be referred to as a first weighing pan). For example, the second weighing pan may enclose the counterbalance wafer, and/or may be configured to form a faraday cage around the counterbalance wafer.

The second weighing pan may be positioned on an opposite side of a pivot to the first weighing pan, such that a moment or torque when the counterbalance wafer is loaded on the second weighing pan is opposite to a moment or torque when the semiconductor wafer is loaded on the first weighing pan.

The weight of the counterbalance wafer may be less than the weight of the semiconductor wafer being measured.

The weighing device may comprise a thermal plate that is configured to contact the counterbalance wafer when there is no semiconductor wafer loaded on the (first) weighing pan.

The thermal plate may maintain the temperature of the counterbalance wafer in thermal equilibrium with the rest of the weighing device. For example, the thermal plate may maintain the temperature of the counterbalance wafer in thermal equilibrium with a measurement chamber surrounding the weighing device.

The thermal plate may be perforated, and/or have one or more grooves, to avoid air cushioning and suction effects as the counterbalance wafer is lifted and replaced on the thermal plate.

A distance from the second weighing pan to the pivot may be less than a distance from the first weighing pan to the pivot.

Additional weight may be added to the (first) weighing pan side of the weighing device, for example at or adjacent to the (first) weighing pan, so that the moment or torque due to the counterbalance wafer is less than the combined moment or torque due to the semiconductor wafer and the additional weight.

The weighing device may comprise a Roberval balance.

The weighing device may comprise a hanging scale mechanism or hanging scale balance.

According to a second aspect of the present invention there is provided an apparatus comprising: a measurement chamber; and the weighing device according to the first aspect of the present invention, wherein the weighing device is inside the measurement chamber.

The apparatus according to the second aspect of the present invention may have any one, or, where compatible, any combination of the following optional features.

The weighing device may have any one, or, where compatible, any combination, of the features of the weighing device of the first aspect of the present invention discussed above.

The apparatus may be a semiconductor wafer metrology apparatus.

The measurement chamber may be for providing a stable measurement environment around the weighing device. For example, the measurement chamber may reduce or prevent air currents around the weighing device, and/or may maintain a uniform temperature around the weighing device. For example, the measurement chamber may comprise a temperature controller for controlling a temperature inside the measurement chamber, such as a heater or a cooler.

The apparatus may be for performing a mass measurement on the semiconductor wafer. The mass of the semiconductor wafer is calculated based at least on the weight measurement on the semiconductor wafer performed by the weighing device.

The apparatus may comprise monitoring means configured to determine the buoyancy exerted on the wafer by the atmosphere in the measurement chamber.

The calculation of the mass of the semiconductor wafer may comprise compensating for the buoyancy exerted on the wafer by the atmosphere in the measurement chamber.

The monitoring means may include one of more of: a temperature monitor, a pressure monitor and a humidity monitor (or temperature sensor, or pressure sensor, or humidity sensor).

The apparatus may include a wafer transport system configured to move wafers onto the weighing pan of the weighing device. The wafer transport system may be configured for transporting wafers having the specific diameter.

According to a third aspect of the present invention there is provided a weighing device for performing a weight measurement on a semiconductor wafer, the weighing device comprising a weighing pan for supporting the wafer during the weight measurement, wherein: the weighing pan is grounded; and the weighing pan is configured to extend over at least 25% of the bottom surface of a 200 mm diameter wafer supported by the weighing pan, or the weighing pan is configured to extend over at least 25% of the bottom surface of a 300 mm diameter wafer supported by the weighing pan, or the weighing pan is configured to extend over at least 25% of the bottom surface of a 450 mm diameter wafer supported by the weighing pan.

The weighing device according to the third aspect of the present invention may have any one, or, where compatible, any combination of the features of the first and/or second aspects described above.

The weighing pan may be configured to extend over at least 30%, or at least 35%, or at least 40%, or at least 45%, or at least 50%, or at least 55%, or at least 60%, or at least 65%, or at least 70%, or at least 75%, or at least 80%, or at least 85%, or at least 90%, or at least 95%, or at least 100% of the area of the bottom surface of the wafer.

The bottom surface of the wafer is the surface of the wafer that faces the weighing pan when the wafer is supported by the weighing pan.

According to a fourth aspect of the present invention there is provided a weighing device for performing a weight measurement on a semiconductor wafer, the weighing device comprising a weighing pan for supporting the wafer during the weight measurement, wherein: the weighing pan is grounded; and the weighing pan extends across an area of at least 0.018 m².

An area of 0.018 m² corresponds to 25% of the surface area of a bottom surface of a 300 mm diameter wafer (to two significant figures). Therefore, when the weighing device is used to perform a weight force measurement on a 300 mm diameter wafer, at least 25% of the bottom surface of the wafer will be covered by the weighing pan. Therefore, charges trapped on at least 25% of the bottom surface of the wafer will result in an attractive force between the wafer and the pan. Such an attractive force will not affect the weight measurement, because the attractive forces on the wafer and pan will be equal and opposite. The weighing pan will therefore shield electrostatic charges on at least 25% of the bottom surface of the wafer. This may significantly reduce errors in the weight measurement caused by electrostatic forces.

The weighing device according to the fourth aspect of the present invention may have any one, or, where compatible, any combination of the features of the first and/or second and/or third aspects described above.

The weighing pan extending across an area of at least 0.018 m² may mean that a surface of the weighing pan that faces a wafer supported by the weighing pan extends across at least 0.018 m².

The weighing pan may extend across an area of at least 0.018 m² facing the wafer supported by the weighing pan.

The weighing pan may extend across an area of at least 0.018 m² when viewed along a direction perpendicular to a wafer supported by the weighing pan.

The weighing pan extending across an area of at least 0.018 m² may mean that when a wafer is supported by the weighing pan, the weighing pan is configured to extend over at least 0.018 m² of a bottom surface of the wafer.

The weighing pan extending across an area of at least 0.018 m² may mean that an outer periphery (or outer edge, or peripheral edge, or circumferential edge, or circumference, or boundary) of the weighing pan encloses an area of at least 0.018 m². Therefore, if the weighing pan includes any holes or perforations, the areas of the holes or perforations are included in the area of at least 0.018 m².

The weighing pan may extend across an area of at least 0.018 m² in a plane parallel to the bottom surface of the wafer supported by the weighing pan.

Extending across an area of at least 0.018 m² may mean extending over an area of at least 0.018 m², or covering an area of at least 0.018 m², or presenting an area of at least 0.018 m², or spanning an area of at least 0.018 m².

The weighing pan may extend across an area of (to two significant figures) at least 0.021 m², or at least 0.025 m², or at least 0.028 m², or at least 0.032 m², or at least 0.035 m², or at least 0.039 m², or at least 0.042 m², or at least 0.046 m², or at least 0.049 m², or at least 0.053 m², or at least 0.057 m², or at least 0.060 m², or at least 0.064 m², or at least 0.067 m², or at least 0.071 m².

According to a fifth aspect of the present invention there is provided a weighing device for performing a weight measurement on a semiconductor wafer, the weighing device comprising a weighing pan for supporting the wafer during the weight measurement, wherein: the weighing pan is grounded; and the weighing pan extends across an area of at least 0.0079 m².

An area of 0.0079 m² corresponds to 25% of the surface area of a bottom surface of a 200 mm diameter wafer (to two significant figures). Therefore, when the weighing device is used to perform a weight force measurement on a 200 mm diameter wafer, at least 25% of the bottom surface of the wafer will be covered by the weighing pan. Therefore, charges trapped on at least 25% of the bottom surface of the wafer will result in an attractive force between the wafer and the pan. Such an attractive force will not affect the weight measurement, because the attractive forces on the wafer and pan will be equal and opposite. The weighing pan will therefore shield electrostatic charges on at least 25% of the bottom surface of the wafer. This may significantly reduce errors in the weight measurement caused by electrostatic forces.

The weighing device according to the fifth aspect of the present invention may have any one, or, where compatible, any combination of the features of the first and/or second and/or third and/or fourth aspects described above.

The weighing pan extending across an area of at least 0.0079 m² may mean that an outer periphery (or outer edge, or peripheral edge, or circumferential edge, or circumference, or boundary) of the weighing pan encloses an area of at least 0.0079 m². Therefore, if the weighing pan includes any holes or perforations, the areas of the holes or perforations are included in the area of at least 0.0079 m².

The weighing pan may extend across an area of (to two significant figures) at least 0.0094 m², or at least 0.011 m², or at least 0.013 m², or at least 0.014 m², or at least 0.016 m², or at least 0.017 m², or at least 0.019 m², or at least 0.020 m², or at least 0.022 m², or at least 0.024 m², or at least 0.025 m², or at least 0.027 m², or at least 0.028 m², or at least 0.030 m², or at least 0.031 m².

According to a sixth aspect of the present invention there is provided a method comprising performing a weight measurement on a semiconductor wafer using a weighing device, wherein the weighing device comprises a weighing pan that supports the wafer during the weight measurement, wherein: the weighing pan is grounded; and the weighing pan extends over at least 25% of an area of a surface of the wafer that faces the weighing pan.

The method according to the sixth aspect of the present invention may have any one, or, where compatible, any combination of the features of the first and/or second and/or third and/or fourth and/or fifth aspects described above.

The weighing pan may extend over at least 30%, or at least 35%, or at least 40%, or at least 45%, or at least 50%, or at least 55%, or at least 60%, or at least 65%, or at least 70%, or at least 75%, or at least 80%, or at least 85%, or at least 90%, or at least 95%, or at least 100% of the area of the surface of the wafer that faces the weighing pan.

In any of the aspects described above, the weighing pan may comprise a plurality of pins that extend from the weighing pan and that are configured to contact the wafer and to support the wafer when the wafer is loaded on the weighing pan. For example, the weighing pan may comprise a plurality of pins that extend from a surface of the weighing pan that faces the wafer.

The invention includes the combination of the aspects and preferred features described except where such a combination is clearly impermissible or expressly avoided.

### BRIEF DESCRIPTION OF THE DRAWINGS

Embodiments of the present invention will now be discussed, by way of example only, with reference to the accompanying Figures, in which:

FIG. 1 shows a known apparatus;

FIG. 2 shows an apparatus according to an embodiment of the present invention;

FIGS. 3(a), (b), (c) and (d) show examples of a weighing pan in embodiments of the present invention viewed from above;

FIG. 4 shows a weighing device according to an embodiment of the present invention;

FIG. 5 shows a weighing device according to an embodiment of the present invention.

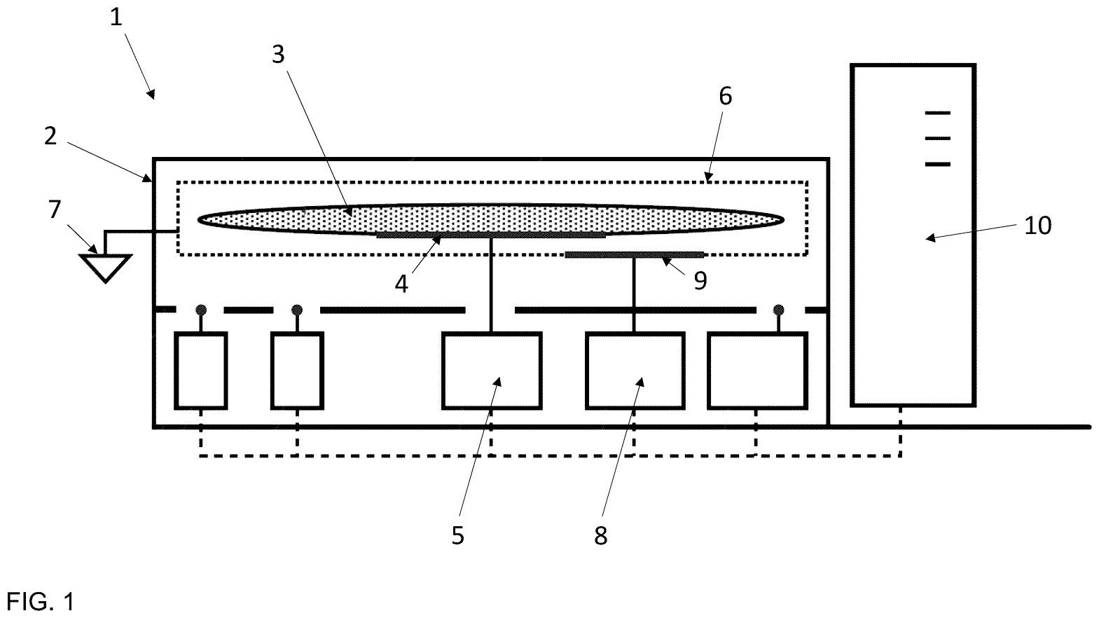

### DETAILED DESCRIPTION OF THE PREFERRED EMBODIMENTS AND FURTHER OPTIONAL FEATURES OF THE INVENTION

Aspects and embodiments of the present invention will now be discussed with reference to the accompanying figures. Further aspects and embodiments will be apparent to those skilled in the art. All documents mentioned in this text are incorporated herein by reference.

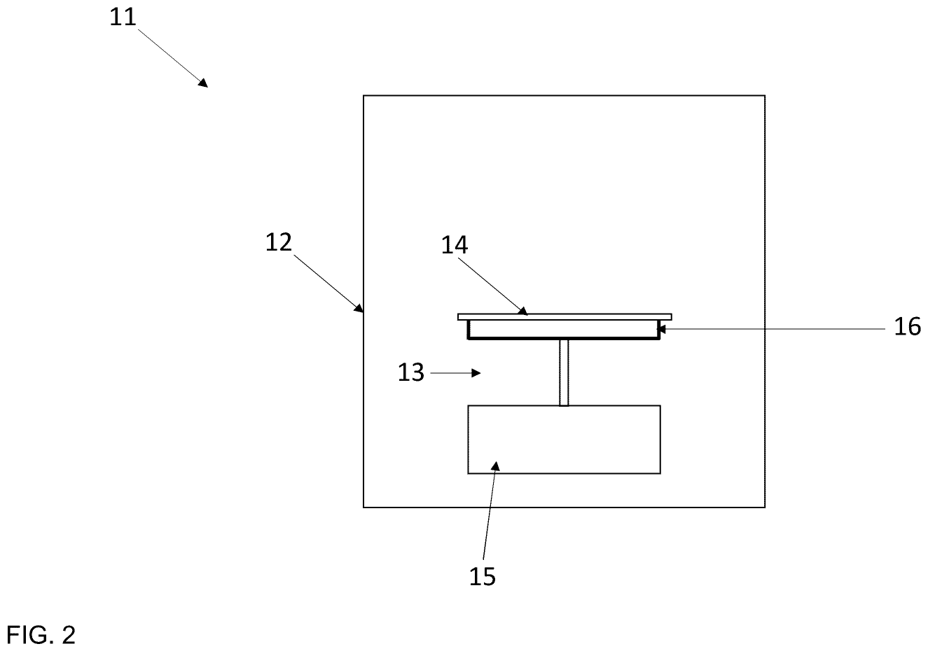

An apparatus 11 according to an embodiment of the present invention is illustrated in FIG. 2. The apparatus 11 comprises a measurement chamber 12. A weighing device 13 for weighing a semiconductor wafer 14 is contained in the measurement chamber 12.

The apparatus 11 may be configured to determine the mass, or a change in the mass, of the semiconductor wafer 14 based on at least a weight measurement performed on the semiconductor wafer 14 by the weighing device 13.

The weighing device 13 is configured to generate measurement output indicative of the weight of the semiconductor wafer 14 loaded on the weighing device 13. For example, the weighing device 13 may measure the weight of the semiconductor wafer 14, or a difference between the weight of the semiconductor wafer 14 and another weight, for example a reference weight or a counterweight.

The measurement chamber 12 provides a controlled environment around the weighing device 13. For example, the measurement chamber 12 may minimise air currents around the weighing device 13. The measurement chamber 12 may also maintain a substantially uniform temperature around the weighing device 13. For example, the measurement chamber 12 may include a heater or cooler for maintaining an interior of the measurement chamber 12 at a substantially uniform temperature, e.g., within +/−0.1° C.

The measurement chamber 12 has an opening (for example a door or window) through which the semiconductor wafer 14 can be inserted into the measurement chamber 12 to be loaded on the weighing device 13.

The apparatus 11 comprises a wafer transport system for transporting wafers from outside the measurement chamber 12 to the weighing device 13 inside the measurement chamber 12.

The weighing device 13 comprises a load cell 15 and a weighing pan 16 that is connected to the load cell 15. The load cell 15 outputs a signal that depends on (corresponds to) a weight of a semiconductor wafer 14 loaded on the weighing pan 16.

The weighing pan 16 is connected to ground and is configured to shield charges on some or all of a bottom surface of the semiconductor wafer 14 that faces the weighing pan 16. Specifically, the weighing pan 16 extends over some or all of the bottom surface of the semiconductor wafer 14, so that the weighing pan 16 is opposite to some or all of the bottom surface of the semiconductor wafer 14.

The apparatus 11 is generally configured to handle wafers having a specific diameter. For example, the apparatus 11 may be configured to handle wafers having a diameter of 200 mm, or 300 mm, or 450 mm. In this embodiment, the apparatus 11 is configured to handle wafers having a diameter of 300 mm. For example, the wafer transport system may be configured to transport wafers having the specific diameter.

A surface of the weighing pan 16 that faces the semiconductor wafer 14 is configured to extend over at least 25% of the area of the bottom surface of the semiconductor wafer 14, so as to shield charges on at least 25% of the area of the bottom surface of the semiconductor wafer 14. In other words, when the semiconductor wafer 14 is supported on the weighing pan 16, at least 25% of the area of the bottom surface of the semiconductor wafer 14 is opposite to the weighing pan 16, so that electrostatic charges on at least 25% of the area of the bottom surface of the semiconductor wafer 14 are shielded by the weighing pan 16.

For a 300 mm diameter semiconductor wafer 14, for example, this means that the surface of the weighing pan 16 that faces the semiconductor wafer 14 extends over an area of at least 0.018 m².

Preferably, the surface of the weighing pan 16 that faces the semiconductor wafer 14 is configured to extend over more than 25% of the bottom surface of the semiconductor wafer 14, such as at least 30%, or at least 35%, or at least 40%, or at least 45%, or at least 50%, or at least 55%, or at least 60%, or at least 65%, or at least 70%, or at least 75%, or at least 80%, or at least 85%, or at least 90%, or at least 95%, or at least 100%.

For example, for a 300 mm diameter wafer, the weighing pan may be configured to extend across an area of (to two significant figures) at least 0.021 m², or at least 0.025 m², or at least 0.028 m², or at least 0.032 m², or at least 0.035 m², or at least 0.039 m², or at least 0.042 m², or at least 0.046 m², or at least 0.049 m², or at least 0.053 m², or at least 0.057 m², or at least 0.060 m², or at least 0.064 m², or at least 0.067 m², or at least 0.071 m².

The surface of the weighing pan 16 that is configured to extend over at least 25% of the area of the bottom surface of the semiconductor wafer 14 may include one or more holes or perforations. Therefore, the area mentioned here is a total area extended over by the weighing pan 16 including the areas of any holes or perforations.

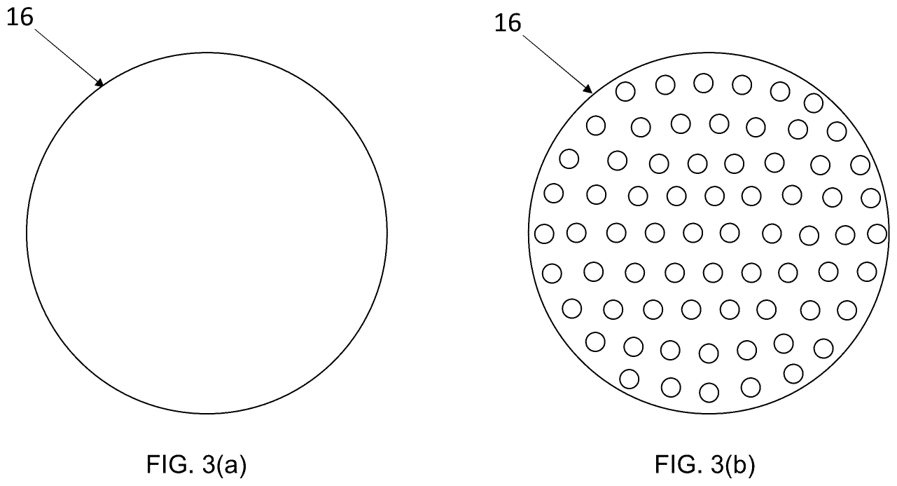

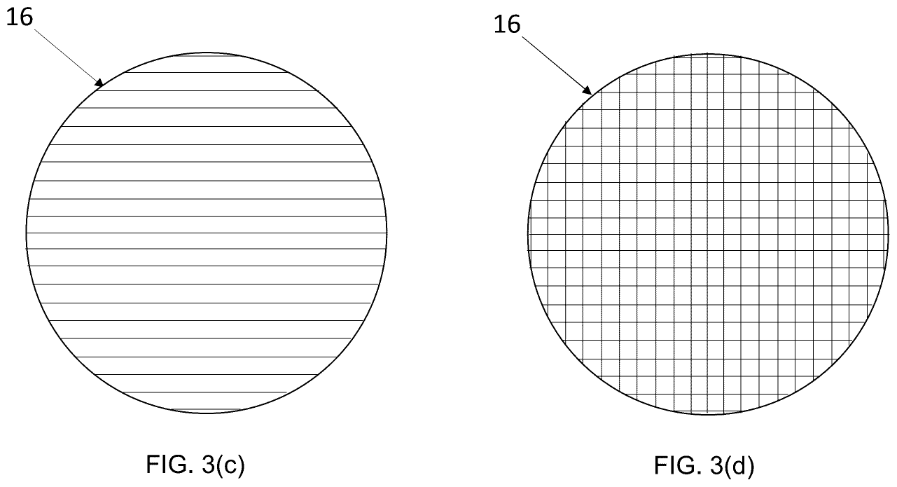

As shown in FIG. 3(a), the surface of the weighing pan 16 that faces the semiconductor wafer 14 may be a continuous surface, without any perforations. Alternatively, the surface may include one or more holes, openings or perforations. For example, the surface may be a perforated surface as illustrated in FIG. 3(b). This may reduce a total weight of the weighing pan 16.

As shown in FIGS. 3(c) and (d), in some embodiments the weighing pan 16, or the surface of the weighing pan 16 that faces the semiconductor wafer 14, may comprise a wire mesh, a wire grid or a plurality of parallel wires that are configured to contact the semiconductor wafer 14 and support the semiconductor wafer 14 when the semiconductor wafer 14 is loaded on the weighing pan 16. The wire mesh, wire grid, or plurality of wires are attached to a circular or cylindrical frame of the weighing pan.

The area referred to above may therefore be an area enclosed by an outer edge, periphery or circumference of the surface of the weighing pan 16 that faces the wafer 14.

In this embodiment the weighing pan has a circular shape when viewed from above (perpendicular to the bottom surface of the semiconductor wafer 14). For a 300 mm diameter wafer, the weighing pan may have a diameter of at least 150 mm, or at least 212 mm, or at least 232 mm, or at least 250 mm, or at least 268 mm, or at least 284 mm, or at least 292 mm, or at least 300 mm.

In another embodiment the weighing pan 16 may be configured to at least partly enclose the semiconductor wafer 14. For example, the weighing pan 16 may additionally comprise a surface that extends across at least part of a top surface of the semiconductor wafer 14 supported by the weighing pan 16.

The weighing pan 16 may form a chamber or housing in which the semiconductor wafer 14 is received. In this case, the weighing pan 16 may have an opening, which may be closable, through which the semiconductor wafer 14 can be inserted into the weighing pan 16.

The weighing pan 16 may be configured to form a faraday cage around the semiconductor wafer 14 supported by the weighing pan 16. The weighing pan 16 may therefore shield all charges on the semiconductor wafer 14, such that all charges on the semiconductor wafer 14 lead to an attractive force between the semiconductor wafer 14 and the weighing pan 16.

As shown in FIG. 2, the weighing pan 16 may be configured to contact the semiconductor wafer 14 at or adjacent to a periphery or outer edge of the semiconductor wafer 14. For example, as shown in FIG. 2, the weighing pan 16 may have a raised lip, edge, or wall at or adjacent to an outer edge of the weighing pan 16 that extends towards the semiconductor wafer 14 to contact the semiconductor wafer 14. This may facilitate correctly positioning the semiconductor wafer 14 on the weighing pan 16 in a predetermined position.

Alternatively, the weighing pan 16 may comprise a plurality of pins that extend from the weighing pan 16 and that are configured to contact the semiconductor wafer 14 and to support the semiconductor wafer 14 when the semiconductor wafer 14 is loaded on the weighing pan 16. For example, the weighing pan 16 may comprise a plurality of pins that extend from a surface of the weighing pan 16 that faces the semiconductor wafer 14. The plurality of pins may be configured to contact the semiconductor wafer 14 at or adjacent to the periphery or outer edge of the semiconductor wafer 14, as illustrated in FIG. 2.

In some embodiments of the present invention, the weighing device may be a counterbalanced weighing device in which part of the weight of the wafer being weighed is cancelled out using a counterbalance. Therefore, the load cell may measure a difference between the weight of the wafer being weighed and a counterbalancing force provided by the counterbalance that cancels out part of the weight of the wafer being weighed.

An advantage of such an arrangement is that the difference being measured will be significantly smaller than the weight of the wafer and can therefore be measured using a higher resolution load cell, giving a better resolution of measurement. In particular, the best resolution available for a load cell is typically a function of the maximum weight that the load cell can measure, such that load cells that measure smaller weights generally have better resolution than load cells that measure larger weights. When weighing semiconductor wafers, the load cell resolution can be a major limiting factor in the overall resolution of the measurement.

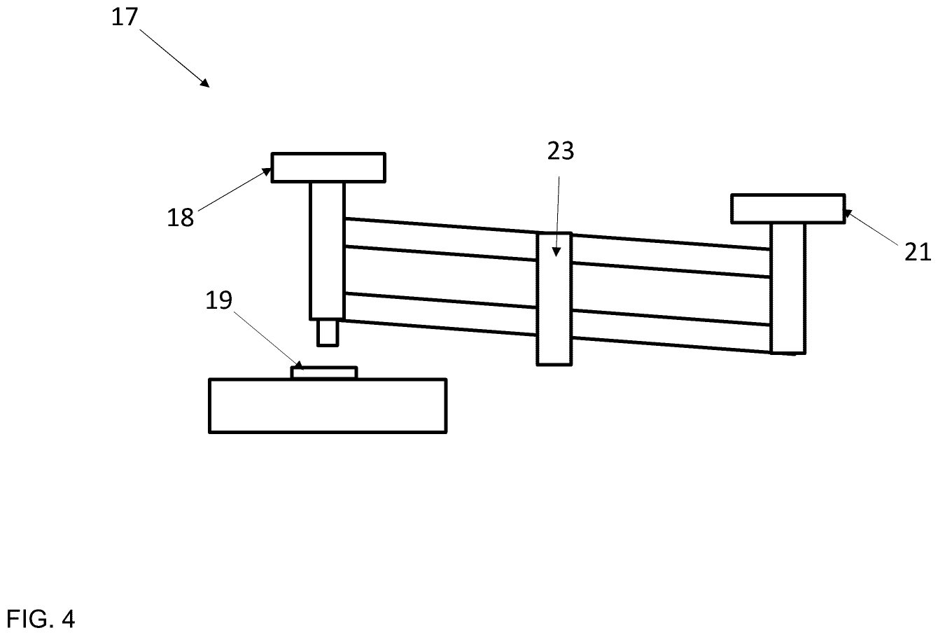

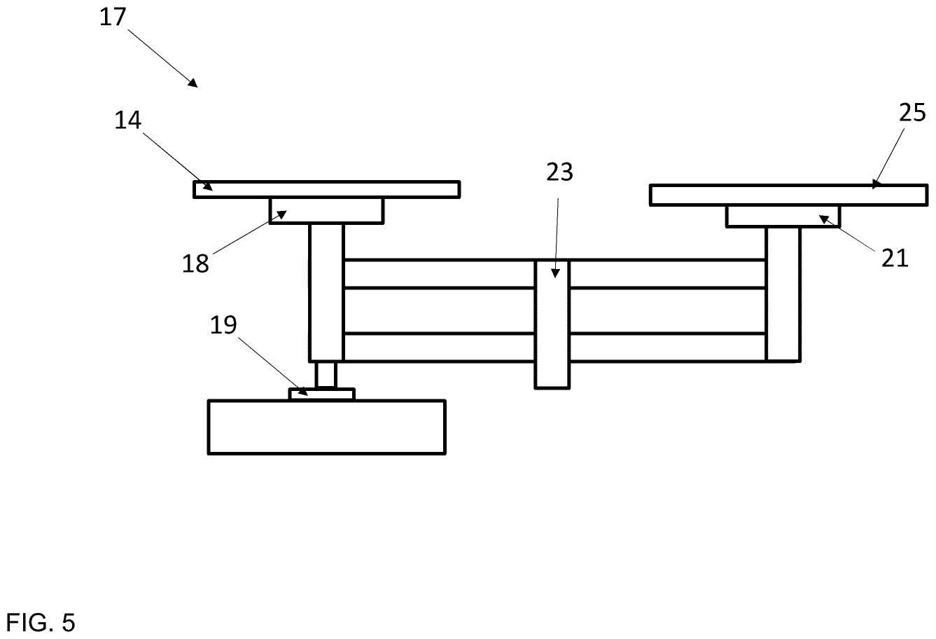

An example of such a counterbalanced weighing device that can be used in embodiments of the present invention is illustrated in FIGS. 4 and 5.

As illustrated in FIGS. 4 and 5, a counterbalanced weighing device 17 according to an embodiment of the present invention comprises a first weighing pan 18 (or balance pan) for supporting a semiconductor wafer 14 being measured. FIG. 4 shows a configuration in which the semiconductor wafer 14 is not supported by the first weighing pan 18, whereas FIG. 5 shows a configuration in which the semiconductor wafer 14 is supported by the first weighing pan 18.

The first weighing pan 18 may have any of the features of the weighing pan 16 discussed above. Specifically, the first weighing pan 18 may be configured to extend over at least 25% of an area of a surface of the semiconductor wafer 14 that faces the first weighing pan 18. In this embodiment, the first weighing pan 18 may be configured to form a faraday cage around the semiconductor wafer 14, so that substantially all electrostatic charges on the semiconductor wafer 14 are shielded by the first weighing pan 18.

A load cell 19 is located beneath the first weighing pan 18 and is configured to measure a weight force of a weight loaded on the first weighing pan 18.

As shown in FIGS. 4 and 5, the weighing device 17 further comprises a second weighing pan 21 (or balance pan) on which a counterweight can be loaded to cancel out part of the weight of the semiconductor wafer 14 measured by the load cell 19, so that the load cell 19 measures the difference between the weight of the semiconductor wafer 14 and counterbalancing force.

Specifically, the first weighing pan 18 and the second weighing pan 21 are connected by one or more beams that are pivoted about a pivot point 23 located between the first weighing pan 18 and the second weighing pan 21. The first weighing pan 18 and the second weighing pan 21 may be connected by two parallel beams that are spaced apart in a vertical direction.

Therefore, the weight of the semiconductor wafer 14 loaded on the first weighing pan 18 causes a moment or torque in a first direction around the pivot point 23 that causes the first weighing pan 18 to move downwards towards the load cell 19. In contrast, a weight loaded on the second weighing pan 21 causes a moment or torque in an opposite second direction around the pivot point 23 that causes the first weighing pan 18 to move upwards away from the load cell 19.

Therefore, the moment or torque provided by a weight on the second weighing pan 21 can cancel out part of the weight force of the semiconductor wafer 14 loaded on the first weighing pan 14, such that the load cell 19 measures a difference between the weight of the semiconductor wafer 14 and the counterbalancing force instead of the whole weight of the semiconductor wafer 14.

The first weighing pan 18 and the second weighing pan 21 may be evenly spaced either side of the pivot point 23.

The one or more beams may be pivotally connected to each of the first weighing pan 18 and the second weighing pan 21.

In one embodiment the weighing device may be a Roberval balance. Such a balance is particularly advantageous because it is not sensitive to positional loading on the first weighing pan 18 and the second weighing pan 21. However, alternative weighing devices could be used instead, for example a hanging scale mechanism or hanging scale balance.

In this embodiment, the counterbalance weight loaded on the second weighing pan 21 is a second semiconductor wafer 25, which may be referred to as a counterbalance wafer 25. The weight of the counterbalance wafer 25 is typically predetermined to be slightly less than the weight of the semiconductor wafer 14 being measured, so that the counterbalancing force provided by the counterbalance wafer 25 cancels out some but not all of the total weight of the semiconductor wafer 14. Alternatively, or in addition, a distance from the second weighing pan 21 to the pivot point 23 may be slightly less than a distance from the first weighing pan 18 to the pivot point 23, so that the moment or torque due to the counterbalance wafer 25 is less than the moment or torque due to the semiconductor wafer 14. Alternatively, or in addition, additional weight may be added to the first weighing pan 18 side of the weighing device 17, for example at or adjacent to the first weighing pan 18, so that the moment or torque due to the counterbalance wafer 25 is less than the combined moment or torque due to the semiconductor wafer 14 and the additional weight.

The second weighing pan 21 may have any of the features of the weighing pan 16 discussed above. Specifically, the second weighing pan 21 may be configured to extend over at least 25% of an area of a surface of the counterbalance wafer 25 that faces the second weighing pan 21. In this embodiment, the second weighing pan 21 may be configured to form a faraday cage around the counterbalance wafer 25, so that substantially all electrostatic charges on the counterbalance wafer 25 are shielded by the second weighing pan 21.

An advantage of the counterweight being a semiconductor wafer is that the counterbalance wafer 25 and the semiconductor wafer 14 being measured have substantially the same volume and density, and are measured under the same environmental conditions. Therefore, the buoyancy forces acting on the semiconductor wafer 14 and the counterbalance wafer 25 will be substantially the same. This means that changes in the buoyancy force will be equally experienced by both the semiconductor wafer 14 and the counterbalance wafer 25 and may effectively cancel each other out. This may reduce or remove the need for measurement correction due to environmental conditions and may improve repeatability of the measurement.

The weighing device 17 may comprise a thermal plate on which the counterbalance wafer 25 is in contact when there is no semiconductor wafer 14 loaded on the first weighing pan 18. The thermal plate may maintain the temperature of the counterbalance wafer 25 in thermal equilibrium with the rest of the weighing device 17.

The thermal plate may be perforated, or have one or more grooves, to avoid air cushioning and suction effects as the counterbalance wafer is lifted and replaced on the thermal plate.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example+/−10%.

1. A weighing device for performing a weight measurement on a semiconductor wafer having a specific diameter,
the weighing device comprising a weighing pan for supporting the wafer during the weight measurement, wherein:
the weighing pan is grounded; and
the weighing pan is configured to extend over at least 25% of an area of a surface of the wafer that faces the weighing pan.

2. The weighing device according to claim 1, wherein the weighing device is for performing a weight measurement on a semiconductor wafer having a diameter of 200 mm, or 300 mm, or 450 mm.

3. The weighing pan according to claim 1, wherein the weighing pan is configured to extend over at least 30%, or at least 35%, or at least 40%, or at least 45%, or at least 50%, or at least 55%, or at least 60%, or at least 65%, or at least 70%, or at least 75%, or at least 80%, or at least 85%, or at least 90%, or at least 95%, or at least 100% of the area of the surface of the wafer that faces the weighing pan.

4. The weighing device according to claim 1, wherein a surface of the weighing pan that faces the wafer is perforated.

5. The weighing device according to claim 1, wherein a surface of the weighing pan that faces the wafer has a thickness of less than 1 mm.

6. The weighing device according to claim 1, wherein the weighing pan is configured to at least partly enclose the wafer supported by the weighing pan.

7. The weighing device according to claim 1, wherein the weighing pan comprises a surface that extends over at least part of a top surface of the wafer supported by the weighing pan.

8. The weighing device according to claim 1, wherein the weighing pan is configured to form a faraday cage around the wafer supported by the weighing pan.

9. The weighing device according to claim 1, wherein the weighing device comprises a counterweight that cancels out part of the weight of the semiconductor wafer supported by the weighing pan.

10. The weighing device according to claim 9, wherein the counterweight is a semiconductor wafer.

11. The weighing device according to claim 10, wherein:
the weight of the counterweight semiconductor wafer is less than the weight of the semiconductor wafer being measured; and/or
additional weight is added to a weighing pan side of the weighing device.

12. The weighing device according to claim 10, wherein the weighing device comprises a second weighing pan for supporting the counterweight semiconductor wafer, and wherein the second weighing pan is configured to extend over at least 25% of an area of a surface of the counterweight semiconductor wafer that faces the second weighing pan.

13. The weighing device according to claim 10, wherein the weighing device comprises a second weighing pan for supporting the counterweight semiconductor wafer, and a distance from the second weighing pan to a pivot of the weighing device is less than a distance from the weighing pan to the pivot.

14. The weighing device according to claim 1, wherein the weighing device comprises a Roberval balance or a hanging scale balance.

15. An apparatus comprising:
a measurement chamber; and
the weighing device according to claim 1, wherein the weighing device is inside the measurement chamber.

16. The apparatus according to claim 15, comprising monitoring means configured to determine the buoyancy exerted on the wafer by the atmosphere in the measurement chamber.

17. The apparatus according to claim 16, wherein the monitoring means includes one of more of: a temperature monitor, a pressure monitor and a humidity monitor.

18. A method comprising:
performing a weight measurement on a semiconductor wafer using a weighing device, wherein the weighing device comprises a weighing pan that supports the wafer during the weight measurement, wherein:
the weighing pan is grounded; and
the weighing pan extends over at least 25% of an area of a surface of the wafer that faces the weighing pan.

19. The method according to claim 18, wherein the weighing pan extends over at least at least 30%, or at least 35%, or at least 40%, or at least 45%, or at least 508, or at least 558, or at least 60%, or at least 65%, or at least 708, or at least 75%, or at least 80%, or at least 858, or at least 908, or at least 95%, or at least 100% of the area of the surface of the wafer that faces the weighing pan.
